(19) United States
(12) Patent Application Publication
(10) Pub. No.: US 2025/0255053 A1
(43) Pub. Date: Aug. 7, 2025

(54) WAVELENGTH CONVERTER AND LED DIE FOR CORRECTING EDGE COLOR SHIFT AND METHODS OF MANUFACTURE

(71) Applicant: LUMILEDS LLC, San Jose, CA (US)

(72) Inventors: Florent Grégoire Monestier, Kerkrade (NL); Ronald Mikkenie, Simpelveld (NL); Yu-Chen Shen, Sunnyvale, CA (US)

(73) Assignee: LUMILEDS LLC, San Jose, CA (US)

(21) Appl. No.: 18/434,517

(22) Filed: Feb. 6, 2024

(51) Int. Cl. H01L 33/50

(52) U.S. Cl. CPC H10H 20/8514; H10H 20/0361; H10H 20/8512

(57) ABSTRACT

A wavelength converter for a shaped surface luminance LED die is described. The wavelength converter produces a peak luminance in a region of the LED die when powered on. The wavelength converter includes a body of a wavelength converting material having a width, a length, and a height. A cross-section of the body in the length direction has a shape such that, when the wavelength converter is installed over the LED die, the height of the body is larger adjacent the region of the LED die that produces the peak luminance.

### BACKGROUND

Light-emitting diodes (LEDs) are increasingly more used in lighting applications, such as automotive lighting systems or general illumination applications, for example, instead of more conventionally used filament lights. In some applications, shaped surface luminance LEDs may be used to control the luminance distribution of light emitted by the LEDs over the surface area of such LEDs. The luminance distribution can be represented in graph form in a luminance map, where a series of peaks and valleys may define the regions of the LED's surface area where the luminance is higher than average or lower than average, with the highest points being termed “peak luminance.”

### SUMMARY

A wavelength converter for a shaped surface luminance LED die is described. The wavelength converter produces a peak luminance in a region of the LED die when powered on. The wavelength converter includes a body of a wavelength converting material having a width, a length, and a height. A cross-section of the body in the length direction has a shape such that, when the wavelength converter is installed over the LED die, the height of the body is larger adjacent the region of the LED die that produces the peak luminance.

### BRIEF DESCRIPTION OF THE DRAWINGS

A more detailed understanding can be had from the following description, given by way of example in conjunction with the accompanying drawings wherein:

FIG. 1 is a diagram of an example conventional wavelength converter for an LED shown in side view (a) and in perspective view (b);

FIG. 2 is a diagram of a luminance map (a), a v′ map (b) and a cross section v′ (c) for a uniform die, such as shown, for example, in FIG. 1;

FIG. 3 is a diagram of an example LED illustrating an edge color shift effect that occurs in the overhang area or areas;

FIG. 4 is a diagram of a luminance map (a), a v′ map (b) and a cross section v′ (c) for an edge shift luminance die, such as shown, for example, in FIG. 3;

FIG. 5 is a diagram of an LED having a wavelength converter with low transparency;

FIG. 6 is a diagram of an LED that includes a top hat shaped wavelength converter that is surrounded on all sides by an optical side coat;

FIG. 7 is a diagram of an example shaped wavelength converter optimized to correct Color over Source (CoS) variation of the shaped surface luminance LED;

FIGS. 8 and 9 are diagrams showing different shapes of example shaped wavelength converters consistent with the embodiments described herein;

FIG. 10 is a diagram of a luminance map (a), a v′ map (b) and a cross section v′ (c) for an asymmetric truncated pyramid wavelength converter, such as the wavelength converting layer of FIG. 7;

FIG. 11 is a diagram of an example simulated v′ cross section graph;

FIG. 12 is a flow diagram of an example method of manufacturing a shaped wavelength converter consistent with the embodiments described herein;

FIG. 13 is a flow diagram of an example method of manufacturing a shaped wavelength converter for a shaped surface luminance LED die;

FIG. 14A is a diagram showing parameters for a blade that can be used to dice a brown body into a wedge shape (e.g., as shown in FIG. 9) using a single pass;

FIG. 14B is a diagram showing parameters for two blades that can be used to dice a brown body into a shape such as shown in FIG. 7 or FIG. 8 using a single pass for each blade;

FIG. 14C is a diagram showing the parameters of a smaller blade that may be used dice a brown body into a shape, such as the wedge shape shown in FIG. 9, using multiple passes;

FIG. 15 is a diagram showing a wavelength converter formed using an additive method at various stages during a method of manufacture; and

FIG. 16 is a flow diagram of an example method of assembling an LED.

### DETAILED DESCRIPTION

Examples of different light illumination systems and/or light emitting diode (“LED”) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

Analysis of some automotive system optics suggests that a shaped surface luminance LED where the peak luminance resides in the center of the LED provides the best system performance for system optics with a total internal reflectance (TIR) lens. On the other hand, LED surface luminance with a gradient from one side to another side may provide the best system performance for system optics with a reflector. This is by contrast to a uniform die where the surface luminance is more evenly disbursed. System optical performance may be evaluated via a system optics figure of merit (FOM), which may evaluate both the intensity and quality of light distribution on the road. In the embodiments described herein, an LED die with a center peak luminance distribution may be referred to as a center peak luminance (CPL) die, and an LED die with edge shift luminance may be referred to as an edge shift luminance (ESL) die. In general, a die with shaped luminance profile may be defined as a die where the luminance averaged over an area equal to at least ten percent (10%) of the entire light emitting area deviates more than twenty percent (20%) of the mean luminance averaged over the entire light emitting area. The area where luminance deviates the most may be referred to as the peak luminance.

While shaped surface luminance LEDs can be advantageous for certain applications, as discussed above, such LEDs can also cause potentially unwanted color variation in the light emitted from the LED. Such variation may be assessed by analyzing, for example, system optical metrics, such as efficacy (which may be determined by Vf and LED flux), color over source (CoS) variation, and/or color over angle and thermal resistance. Strong CoS variation may be particularly important as it can lead to dramatic and unpleasant color variation of the projected light on the road.

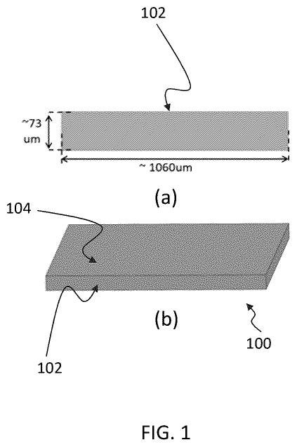

FIG. 1 is a diagram of an example conventional wavelength converter 100 for a uniform LED die shown in side view (a) and in perspective view (b). In the example illustrated in FIG. 1, the wavelength converter 100 may have a top surface 104, a bottom surface (not visible in FIG. 1) opposite the top surface, and at least one side surface 102. As can be seen in the side view in (a), the wavelength converter has a uniform surface profile defined by a uniform height across the entire side surface 102. In the example illustrated in FIG. 1, the wavelength converter 100 has a uniform height of approximately 73 μm and a width of approximately 1060 μm, although the dimensions may vary depending on design constraints, for example.

In the example illustrated in FIG. 1, the wavelength converter 100 may be a ceramic phosphor platelet. However, one of ordinary skill in the art will understand that other types of wavelength converters, such as phosphor in silicone or phosphor in glass, may be used. Unless otherwise specified, the term wavelength converter, as used throughout, may include one or more layers of any type of wavelength converting material, including, but not limited to, a ceramic phosphor platelet, phosphor in silicone or phosphor in glass.

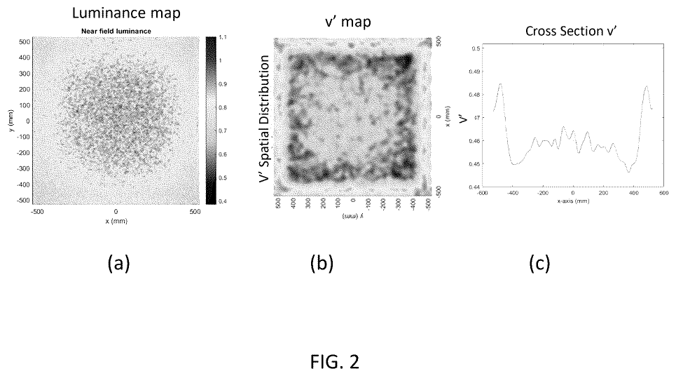

FIG. 2 is a diagram of a luminance map (a), a v′ map (b) and a cross section v′ (c) for a uniform die. The uniform die may be, for example, a standard 1 mm² uniform die. In the example illustrated in FIG. 1, for the uniform die, the luminance map is largely centered with respect to the surface area of the LED (i.e., peak intensity is largely centered in the die) and there are relatively small variations v′ in light intensity.

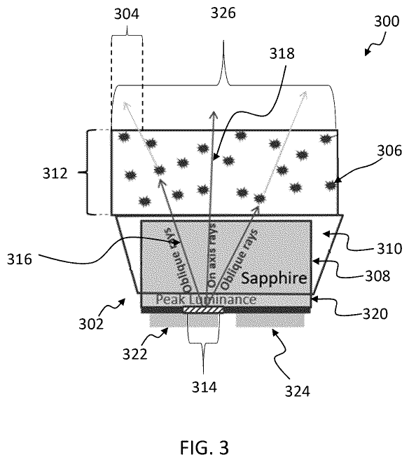

FIG. 3 is a diagram of an example ESL LED 300. In the example illustrated in FIG. 3, the LED 300 includes an LED die 308, which may include epitaxial layers 320 on a substrate 308, such as a sapphire substrate. A wavelength converter 312 is disposed over the LED die 302 and may be secured to the LED die 302 such as via an adhesive 310. A top surface of the wavelength converter 312 may be referred to as the light-emitting area (LEA) 326 where light is emitted from the LED 300. In the example illustrated in FIG. 3, the LEA 326 takes up the entirety of the top surface of the wavelength converter 312, although one of ordinary skill in the art will understand that the LEA in practice will likely take up less than the entirety of the top surface. Conductive contacts 322 and 324 may be disposed on or near a bottom surface of the LED die 308, which may be used to provide current to drive the LED 300, from an external power source (not shown), to power it on and off. The conductive contacts 314 may be shaped and located in such a manner to promote current injection into specific parts of the die (as illustrated in FIG. 3).

In some embodiments, a highly reflective material (not shown in FIG. 3), such as an optical side coat, may be placed around the side surface or side surfaces of the LED die 302 and the wavelength converter 312 to avoid light emission from the LED 300 in areas other than the LEA 326. In the example illustrated in FIG. 3, the wavelength converter 312 overhangs the LED die 302 in an overhang area 304. The wavelength converter 312 may overhang the LED die 302 on all sides.

FIG. 3 illustrates an edge color shift effect that occurs in the overhang area or areas 304. The overhang area or areas 304 may be required to avoid having blue rays that do not pass through the platelet. In practice, the wavelength converter 312 may be a few tens of micrometers larger than the LED die 302 to take into account variation due manufacturing tolerance and platelet misalignment.

As can be seen in FIG. 3, the LED die 320 emits on axis rays 318 and oblique rays 316. The on axis rays may pass through the wavelength converter 312 unconverted, and the oblique rays may be absorbed by phosphor particles 306 in the wavelength converter 312 and re-emitted as rays of a different color. In the peak luminance area 314, for example, due to geometric conditions, the LED die 320 emits many more oblique rays that travel a longer distance through the wavelength converter 312 than on axis rays 318. This may result in an edge color shift phenomena where the light emitted through the wavelength converter 312 may appear more yellow to the viewer in areas away from the peak luminance area 314 than in the peak luminance area 314. Accordingly, LEDs, such as the LED 300 illustrated in FIG. 3, may have the strong disadvantage of having high CoS variation.

This edge color shift phenomena tends to occur in all shaped surface luminance LEDs based on non-uniform current distribution, which may also have the disadvantage of strong CoS variation. Similar to the LED 300 illustrated in FIG. 3, for such shaped surface luminance LEDs based on non-uniform current distribution, light emitted via the part away from the peak luminance area may appear more yellow than light emitted via the peak luminance area.

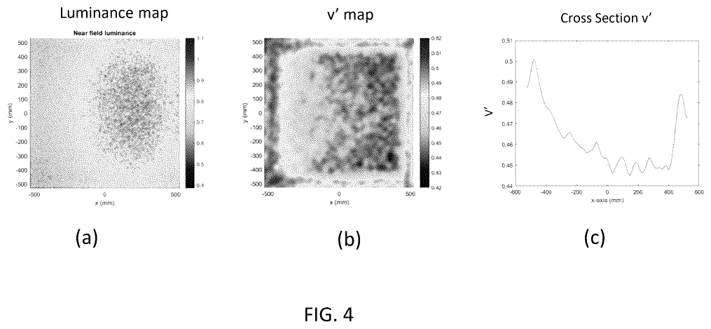

FIG. 4 is a diagram of a luminance map (a), a v′ map (b) and a cross section v′ (c) for an edge shift luminance die, such as shown, for example, in FIG. 3. In comparison with the diagram provided in FIG. 2, the edge shift luminance die has a minimum of 50 points variation of v′ between the peak luminance area and the platelet overhang area. It should be noted that color variation over surface will depend directly on luminance uniformity and associated current uniformity. The more the current uniformity over the LEA of the LED is, the higher will be the CoS variation. Unlike the uniform die, the most white-bluish area of the ESL die matches with the peak luminance area. It is very critical for system optic performance as this peak luminance area will contribute the most to the cut-off color in low beam automotive optical system or to the peak intensity in an automotive high beam optical system.

Conventional shaped luminance LEDs are designed to promote current injection into specific parts of the LED die. However, this method leads to strong CoS variation, as shown in FIGS. 3 and 4 and described above, as oblique rays emitted near the peak luminance area will be more converted than rays emitted in the center of the die.

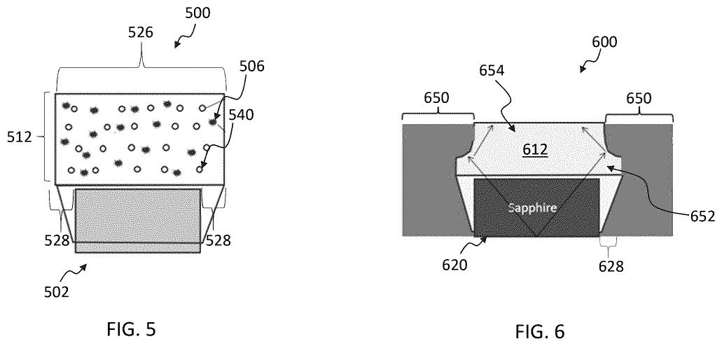

FIG. 5 is a cross-sectional view of an LED 500 having a wavelength converter 512 with low transparency. As illustrated in FIG. 5, a conventional means of solving the strong CoS variation in conventional shaped luminance LEDs may be to use a wavelength converter 512 that is thick and has low transparency by providing a high density of scattering air pores 540. Such high density of scattering air pores 540 may scatter light in all directions, resulting in better color mixing of light emitted via the LEA 526. All other parts of the LED 500 may be the same as, or similar to, the LED 300 illustrated in FIG. 3. For example, the wavelength converter 512 may also include phosphor particles 506, and the wavelength converter may be disposed over an LED die 502, which may be the same as or similar to the LED die 302 of FIG. 3. While the LED 500 may slightly improve edge color shift by providing better color mixing, the LED 500 may also reduce optical flux and surface luminance as interaction with the optical side coat (not shown but described above with respect to FIG. 3) may be higher.

FIG. 6 is a cross-sectional view of an LED 600 that includes a top hat shaped wavelength converter 612 that is surrounded on all sides by an optical side coat 650. In the example illustrated in FIG. 6, the wavelength converter 612 has a brim region 652 that is adjacent the top surface of an LED die 620, only the substrate of which is labeled in FIG. 6. While the substrate is labeled sapphire in FIG. 6, any suitable type of substrate can be used for the LED die 620 as would be understood by one of ordinary skill in the art. A crown portion 654 of the wavelength converter 612 extends upward from the brim giving the wavelength converter 612 the shape of an upside down top hat.

In the example illustrated in FIG. 6, the brim region 652 of the wavelength converter 612 is completely covered on all side surfaces by a diffuse, scattering, optical side coat 650. This may reduce the color shift on the brim region 652 of the wavelength converter 612 as almost no light will be emitted via the overhang area 628 (only one of which is labeled in FIG. 6). However, such design will also reduce optical flux and requires a thick wavelength converter 612 to be sure that no light is emitted above the brim region 652. In some cases, for example, the wavelength converter may be as thick as approximately 200 μm or more.

Embodiments described herein may provide for a shaped surface luminance LED that may provide the lowest CoS variation without comprising system FOM performance (e.g., based on quality of light distribution and flux on the road). Such embodiments reduce the optical path through the wavelength converter of an LED towards the outer edges of the wavelength converter. This may be accomplished, for example, by cutting one or more corners of the wavelength converter on the emission side.

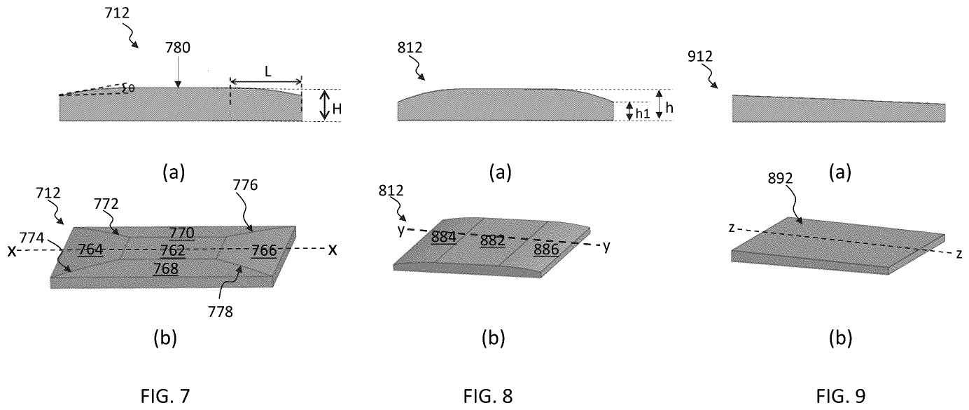

FIG. 7 is a diagram of an example shaped wavelength converter 700 optimized to correct CoS variation of the shaped surface luminance LED. The shaped wavelength converter 700 is shown in cross-sectional view taken along the line x-x (a) and perspective view (b). In the example illustrated in FIG. 7, the wavelength converter 712 is for a 1 mm² LED die (not shown) and has four side surfaces 764, 766, 768 and 770 and a top surface 762. One or more of the edges 772, 774, 776 and 778 between side surfaces 764, 766, 768, and 770 may be curved or sloped. In the example illustrated in FIG. 7, all four of the edges 772, 774, 776 and 778 are curved. In the cross-sectional view (a), the general cross-sectional shape of the wavelength converter can be seen. Each of the edges 772, 774, 776 and 778 is curved, and the curved shape has a corresponding angle θ and a length of curvature L. The shaped wavelength converter 700 may be designed for use with a standard 1 mm² LED die. How to choose values for θ to apply the teachings herein to other sizes of LED dies will be evident from the methods described below.

To correct the strong CoS variation that would otherwise be exhibited by the shaped surface luminance LED, at least one edge 772, 774, 776 and/or 778 may be curved on the emission side (e.g., the side of the LED die on which the LEA is located—labeled as 780 in FIG. 7 for clarity). In the example illustrated in FIG. 7, the value of θ is larger on the die side opposite the peak luminance side.

For a wavelength converter, such as the wavelength converter 712 illustrated in FIG. 7, the height H of the wavelength converter 712 decreases from the center toward the outer edge of the wavelength converter 712. In other words, the wavelength converter 712 has an asymmetric truncated pyramid shape. This smooth height reduction may provide lower conversion efficiency and therefore less yellow conversion of oblique rays, which compensates for higher conversion due to the dominance of oblique rays on the overhang area, for example. The corner shape may not necessarily be linear (chamfer) but may also be curved, for example, with the steepest slope on the die side situated on the opposite side of the peak luminance. Such corner shapes may be collectively referred to herein as curved cut corners. In some embodiments, the edges may only be curved or otherwise sloped on the die side opposite peak luminance. In other embodiments, such as illustrated in FIG. 7, all four edges may be curved or otherwise sloped but the edges on the side opposite peak luminance may have a steeper slope (0) than the edges on the peak luminance side of the LED die.

FIGS. 8 and 9 are diagrams showing different cross-sectional shapes of example wavelength converters consistent with the embodiments described herein. The shaped wavelength converter 812 is shown in cross-sectional view taken along the line y-y (a) and perspective view (b). In the example illustrated in FIG. 8, the wavelength converter 812 has two side surfaces 884 and 886 and a top surface 882. Each of the side surfaces 884, 886 is curved, and the value of the angle θ of curvature is steeper on the side opposite peak luminance of the underlying LED die, similar to FIG. 7. The shape of the wavelength converter in FIG. 8 can be described as having a ramp shape. The shaped wavelength converter 912 is shown in cross-sectional view taken along the line z-z (a) and perspective view (b). In the example illustrated in FIG. 9, the wavelength converter 912 has a single top surface 892 that is sloped (or in other words, the wavelength converter 912 is wedge-shaped), and the value of the angle θ of curvature is chosen to permit the height H of the wavelength converter 912 to be lower on the side opposite peak luminance of the underlying LED die.

For embodiments such as shown in FIGS. 7 and/or 8, the length L (illustrated in FIG. 7 only but applicable to FIG. 8) extends from a minimum of approximately 50 μm to a maximum of approximately 2/4 of the length of the LED die. The wavelength converter height L will be higher on the peak luminance side of the LED die, as described in detail above.

As mentioned above, different wavelength converter shapes are possible. When the value or values of the curved corner angle or angles θ is/are greater on the die side opposite peak luminance, regardless of how many curved sides or edges the wavelength converter has, the wavelength converter will have an asymmetric shape where the surface or edges on the die side opposite peak luminance has a steeper slope. Referring to FIG. 7, in an embodiment optimized for a standard 1 mm² LED die, the curved cut corner angle on the die side opposite peak luminance (e.g., angle of surface 764 and edges 772 and 774) is approximately 12.5° while the curved cut corner angle of edges 776 and 778 (on the side of peak luminance) is approximately 7°. The curved cut corner length L is approximately 300 μm or roughly ⅓ the length of the die.

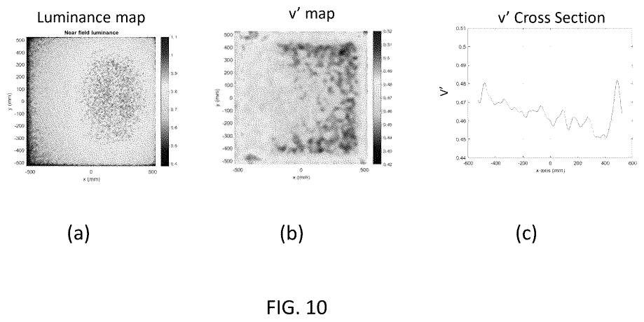

FIG. 10 is a diagram of a luminance map (a), a v′ map (b) and a cross section v′ (c) for an asymmetric truncated pyramid wavelength converter, such as the wavelength converter 712 of FIG. 7. As can be seen in FIG. 10 as compared, for example, to FIG. 3, the luminance map still shows the peak luminance values shifted to the right. However, the v′ cross section is much flatter than in FIG. 3, indicating that the asymmetric truncated pyramid wavelength converter provides a much lower CoS variation than the conventional wavelength converter for the standard 1 mm² LED die.

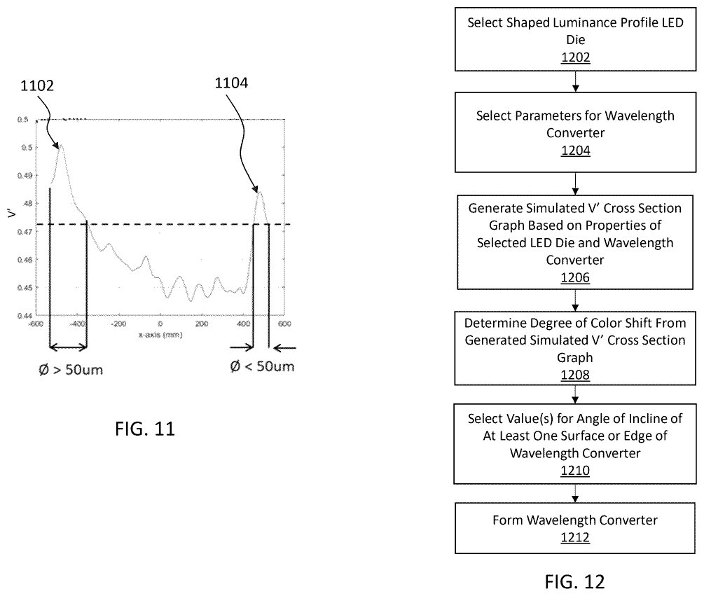

FIG. 11 is a diagram of an example simulated v′ cross section graph. The diagram was generated based on certain properties of the underlying LED die (e.g., size) and the wavelength converter (e.g., material). In the example illustrated in FIG. 11, the diagram was generated by taking an average of v′ over a 100 μm band in the y direction and over the full die length in the x direction for a given LED used in conjunction with a converter, such as shown in FIG. 7. As mentioned above, if there is any change in the converter design, such as scattering power, different material, different dopant, small die design change, die design with more pronounced gradient, etc., the graph will change. The dashed line in FIG. 11 represents the mean value of v′ over the entire surface of the LEA of a chosen LED die. An analysis of the graph may provide the optimized value for θ, as described in detail immediately below.

FIG. 12 is a flow diagram of an example method of manufacturing a wavelength converter consistent with the embodiments described herein. In the example illustrated in FIG. 12, as mentioned above with respect to FIG. 11, a shaped luminance profile LED die may be chosen (1202) for a given application based on application specifications, for example. For the embodiments described herein, a shaped luminance profile LED die will be chosen. The chosen shaped luminance profile LED die will have certain parameters that may work best for a particular application, for example, such as the size of the LED die. Parameters for the wavelength converter (other than its shape) may be selected (1204). For example, a material or materials for the wavelength converter may be chosen, such as a ceramic phosphor or phosphor in another medium, such as silicone or glass. For purposes of this example method, assume that a standard shaped luminance profile LED die having a size of 1 mm² is chosen and that the wavelength converter will be formed from a ceramic phosphor.

A simulated v′ cross section graph may be generated based on properties of the selected die and wavelength converter (1206). A degree of color shift may be determined from the simulated v′ cross section graph (1208). This can be determined by looking at the portions of the curve in the graph that are above the dashed line, which represents the mean value of v′ over the entire surface of the LEA. It can be seen, from the graph in FIG. 11, for example, that there are two continuous sections of the curve that are above the dashed line, one on the left hand side and one on the right hand side. If the diameter of a continuous section of the curve that is above the dashed line is greater than (>) approximately 50 μm, that section may be considered to represent a large degree of color shift. If, on the other hand, the diameter of a continuous section of the curve that is above the dashed line is less than (<) approximately 50 μm, that section may be considered to represent a small degree of color shift. In the example illustrated in FIG. 11, the curved section 1102 has a diameter >50 μm, and, accordingly, is considered to have a high degree of color shift. The curve section 104 has a diameter <50 μm and, accordingly, is considered to have a low degree of color shift.

Values for the angle of inclination of at least one surface or edge of the wavelength converter may be selected (1210), for example, based on the determination in 1208. A rule can be established such that the angle between the tangent of the curvature (on the outset point) and horizontal line should be higher than 10° to correct a large degree of color shift (>50 μm) and can be lower than 10° to correct a small degree of color shift (<50 μm). The angle between the tangent of the curvature (on the outset point) and a horizontal line are represented by θ in FIG. 7 and can be similarly defined for other shapes, such as shown in FIGS. 8 and 9, as would be apparent to one of ordinary skill in the art. For the example illustrated in FIG. 11, and assuming an asymmetric, truncated pyramid shaped wavelength converter, θ for the two edges on the peak luminance side of the LED may be chosen to be 12.5°. θ for the two edges on the non-peak luminance side of the LED may be chosen to be 7.0°.

Alternatively, or in addition, a rule can be established based on platelet height. For example, a rule can be established that a height at the outside point of the platelet to a maximum height of the platelet should be less than a threshold amount. The various platelet heights are illustrated, for example, in FIG. 8, where h₁ is the height at the outside point of the platelet and h is the maximum platelet height (e.g., in the center of the platelet). An example rule could be h₁/h<0.8.

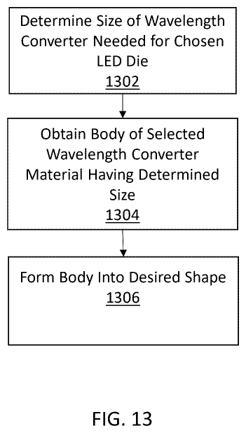

The wavelength converter may then be formed (1212) using the selected shape and materials. FIGS. 13-16 illustrate examples of methods that can be used to manufacture the wavelength converter described herein.

FIG. 13 is a flow diagram of an example method of manufacturing a wavelength converter for a shaped surface luminance LED die. In the example illustrated in FIG. 13, a size of a wavelength converter needed for the chosen LED die (see 1202 in FIG. 12) is determined (1302). A body of the selected wavelength converter material (see 1204 in FIG. 12) having the size determined in 1302 may be selected (1304). The body may be formed into the determined shape (1306) (see FIG. 12). Optionally, in some embodiments, the body may be heated, as described below where applicable.

Using the method of FIG. 13 as guidance, a number of different methods can be used to manufacture the wavelength converter. In an example embodiment, material subtractive methods, such as dicing or laser ablation techniques, can be used to form the wavelength converter. According to such methods, obtaining the body of selected wavelength material in 1304 of FIG. 13 may include obtaining one or more densified, rectangular, ceramic wafers or obtaining a brown body, for example. The brown body may be a body of ceramic particles. The organic particles may be burnt off, but the body may have high mechanical strength due to partial sintering of oxide powders.

In some embodiments, dicing may be used to remove material from a brown body to create a shaped platelet wavelength converter. In such embodiments, the shape may be formed using a dicing blade specifically designed for making the chosen shape (e.g., shapes shown in FIGS. 7, 8 and 9 and described above).

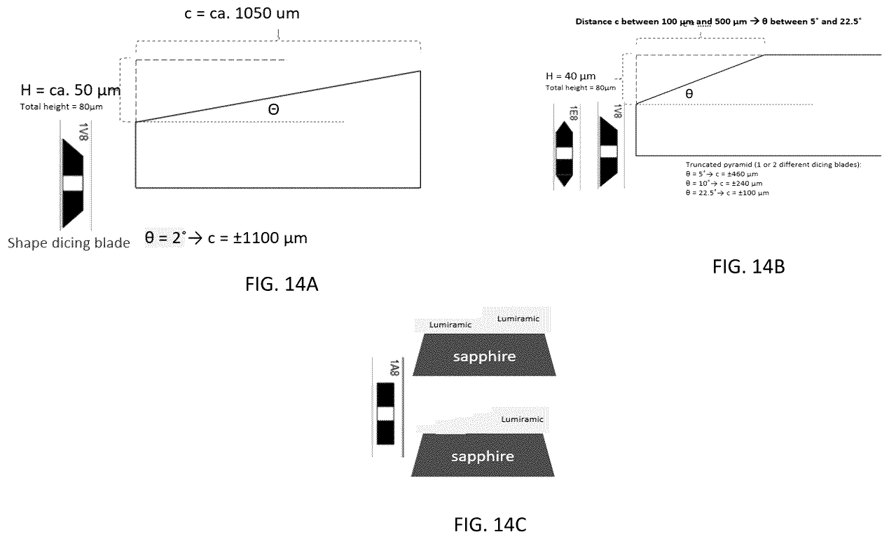

FIG. 14A is a diagram showing the parameters fora blade that can be used to dice the brown body into a wedge shape (e.g., as shown in FIG. 9) using a single pass. In the example illustrated in FIG. 14A, a special dicing blade according to the dimensional specification for the wavelength converter is made and used to dice the brown body into the wedge shape. As can be seen in FIG. 14A, the blade is a sharp dicing blade, which can be dimensioned based on chosen parameters for the platelet. A second cut may be made in the x and y directions to separate the wafer into platelets.

FIG. 14B is a diagram showing the parameters of two blades that can be used to dice the brown body into a shape such as shown in FIG. 7 or FIG. 8 using a single pass for each blade. In a first pass, a broad dicing blade may be used to cut part, or half-way, into the height of the body. A smaller blade, such as shown in FIG. 14B, can then be used to cut the rest of the way through the height of the body (e.g., in the x-direction) to form a step-shaped body. The body may then be diced in the y-direction to produce individual platelets. In embodiments, multiple steps can be created by starting with a wider blade and using smaller blade widths and different cutting depths to produce the desired number of steps.

FIG. 14C is a diagram showing the parameters of a smaller blade that may be used to make a shape, such as the wedge shape shown in FIG. 9, using multiple passes. In a first pass, a sharp blade can be used of different width and different tip angle as desired to make the shape. A second pass can be made with a different blade in the x and y directions to separate the wafer into individual platelets.

Alternatively, the various shaped wavelength converters can be made by removing material from the brown body using, for example, ding or and/or laser ablation processes. In such embodiments, material from the body may be removed in multiple passes. The use of a laser, such the femto-laser, may enable more freedom to create a shape, such as the ones described above with reference to FIGS. 7, 8 and 9.

After shaping, using any of the methods described with respect to FIGS. 14A, 14B and 14C, the brown body or bodies may be further densified in a heating cycle (see 1308 FIG. 13).

In other example embodiments, material additive methods can be used to form the wavelength converter. According to such methods, obtaining the body of selected wavelength material in 1304 of FIG. 13 may include obtaining a green body. The green body may be, for example, a body of bonded powder or plates, including, for example, a mixture of ceramic material, at least one phosphor material, and any other needed or desired additives, obtained prior to sintering

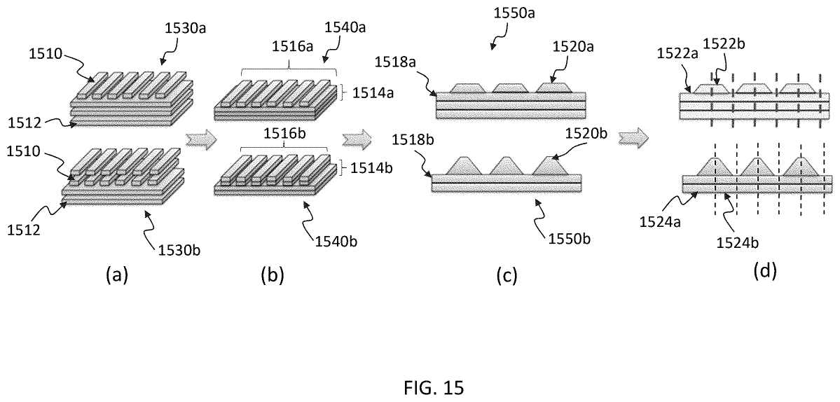

FIG. 15 is a diagram showing a wavelength converter formed using an additive method at various stages during a method of manufacture. In the example illustrated in FIG. 15, in (a), multiple green body pieces 1510, 1512 are arranged and laminated in a pattern 1530a, 1530b, respectively. In FIG. 15, two arrangements are shown that may be further processed to produce wavelength converters having different shapes. Additionally, in FIG. 15, two different shaped green body pieces 1510 and 1512 are used to form the patterns. The pieces 1510 are bar shaped while the pieces 1512 are plate-shaped. The pieces may be green tapes or other smaller pieces of green body material. At the top in (a), three rows of green body pieces 1512 are stacked with a single row of green body pieces 1510 on top. At the bottom in (a), only two rows of green body pieces 1512 are stacked with two rows of green body pieces 1510 stacked on top. As mentioned above, each patterned stack in (a) may be laminated to form green bodies shown in (b). In (b), a green body 1540a on the top of the drawing includes a laminated stack 1514(a) of green body material and a series of bars 1516a of green body material laminated on top. A green body 1540b on the bottom of the drawing includes a laminated stack 1514b of green body material and a series of double-stacked bars 1516b laminated on top.

The green bodies 1540a and 1540b shown in (b) may then be subjected to isostatic pressing to form deformed green wafers 1550a and 1550b, respectively. In the process, the top layer or layers (i.e., the bar-shaped green body pieces) may be shaped to form a deformed green body wafer, which may then be separated to form a number of individual wavelength converters. In some embodiments, for the isostatic pressing, a negative mask can be used for an embossing technique during the pressing. The bar-shaped green body pieces 1510 may need to be formed from a very low green density material to enable the bar-shaped pieces 1510 to be deformed during ISP. In such embodiments, the green body material will flow under stress due to high pressure using the mask to define the shape. Choosing the geometrical design of the press dies, the target shape of green body can be made and sintered into the optical densified ceramic bodies 1550a and 1550b shown in (c). As can be seen in (c), two different shaped top layers 1520a and 1520b are formed by changing the pattern 1530 and/or shape of the green body pieces and using a different mold during the isostatic pressing. The wafers 1550a, 1550b can be diced or otherwise separated along dicing lanes (indicated by the dashed lines in (d)) to form individual wavelength converters (e.g., ceramic phosphor platelets) 1552, 1554 (only 1552a, 1522b, 1524a and 1524b are labeled in FIG. 15).

In some embodiments, the green bodies can be made using slip-casting. Use of a mold may also be necessary using this technique to create the different shaped top layers (e.g., same as or similar to the shaped top layers 1520a, 1520b in FIG. 15). In some embodiments, the green body may be formed using 3D printing, such as inkjet printing. The 3D-printed green bodies may be in wafer form, which can be diced after sintering to create the individual wavelength converters, or can be made in the form single platelets.

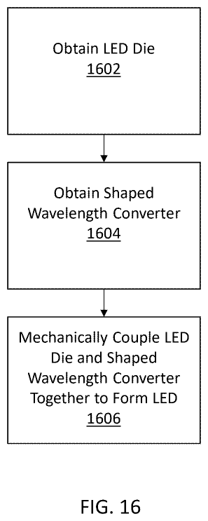

FIG. 16 is a flow diagram of an example method of assembling an LED. In the example illustrated in FIG. 16, an LED die may be obtained (1602). The LED die may, for example, be the shaped surface luminance LED die selected in 1202 in FIG. 12. The selecting may include selecting an LED die off the shelf or as made by another manufacturer or manufactured elsewhere or may include manufacturing an LED to the required specifications. A shaped wavelength converter may be obtained (1604). The obtaining may include obtaining a shaped wavelength converter from another manufacturer or that was manufactured elsewhere or manufacturing the wavelength converter as described in some or all of the methods above. The LED die and the shaped wavelength converter may be mechanically coupled together (1606) to form an LED. The two workpieces may be mechanically coupled together using any known technique, such as gluing.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. Examples of computer-readable media include electronic signals (transmitted over wired or wireless connections) and computer-readable storage media. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

What is claimed is:

1. A wavelength converter for a shaped surface luminance light-emitting diode (LED) die that produces a peak luminance in a region of the LED die when powered on, the wavelength converter comprising:
a body of a wavelength converting material having a width, a length, and a height, wherein a cross-section of the body in the length direction has a shape such that, when the wavelength converter is installed over the LED die, the height of the body is larger adjacent the region of the LED die that produces the peak luminance.

2. The wavelength converter of claim 1, wherein the shape of the cross-section of the body in the length direction is an asymmetric truncated pyramid.

3. The wavelength converter of claim 2, wherein the body has four side surfaces and a top surface, wherein each of the four sides surfaces is separated from two adjacent ones of the four side surfaces by one of four edges, wherein each of the four edges has a curved shape, and wherein two of the four edges that are adjacent the region of the LED die that produces the peak luminance, when the wavelength converter is installed over the LED die, have a smaller slope than two of the four edges that are not adjacent the region of the LED die that produces the peak luminance.

4. The wavelength converter of claim 1, wherein the body has two side surfaces separated from one another by a top surface, and wherein the shape of the cross-section of the body in the length direction is such that one of the two side surfaces that is adjacent the region of the LED die that produces the peak luminance when the wavelength converter is installed over the LED die has a smaller slope than the other one of the two sides surfaces that is not adjacent the region of the LED die that produces the peak luminance.

5. The wavelength converter of claim 1, wherein the body has a wedge shape.

6. The wavelength converter of claim 1, wherein the wavelength converting material is one of a ceramic phosphor, phosphor in silicone, or phosphor in glass.

7. The wavelength converter of claim 1, wherein the body is a platelet.

8. A shaped surface luminance light-emitting diode (LED) comprising:
an LED die that produces a peak luminance in a region of the LED die when powered on; and
a wavelength converter, over the LED die, wherein the wavelength converter comprises a body of a wavelength converting material having a width, a length, and a height, wherein a cross-section of the body in the length direction has a shape such that, when the wavelength converter is installed over the LED die, the height of the body is larger adjacent the region of the LED die that produces the peak luminance.

9. The shaped surface luminance LED of claim 8, wherein the shape of the cross-section of the body in the length direction is an asymmetric truncated pyramid.

10. The shaped surface luminance LED of claim 9, wherein the body has four side surfaces and a top surface, wherein each of the four sides surfaces is separated from two adjacent ones of the four side surfaces by one of four edges, wherein each of the four edges has a curved shape, and wherein two of the four edges that are adjacent the region of the LED die that produces the peak luminance, when the wavelength converter is installed over the LED die, have a smaller slope than two of the four edges that are not adjacent the region of the LED die that produces the peak luminance.

11. The shaped surface luminance LED of claim 8, wherein the body has two side surfaces separated from one another by a top surface, and wherein the shape of the cross-section of the body in the length direction is such that one of the two side surfaces that is adjacent the region of the LED die that produces the peak luminance when the wavelength converter is installed over the LED die has a smaller slope than the other one of the two sides surfaces that is not adjacent the region of the LED die that produces the peak luminance.

12. The shaped surface luminance LED of claim 8, wherein the body has a wedge shape.

13. The shaped surface luminance LED of claim 8, wherein the wavelength converting material is one of a ceramic phosphor, phosphor in silicone, or phosphor in glass.

14. The shaped surface luminance LED of claim 8, wherein the body is a platelet.

15. A method of manufacturing a light-emitting diode (LED), the method comprising:
selecting a shaped luminance LED die that is configured to emit light, when powered on, such that the light has a peak luminance in a region of the LED die;
producing a wavelength converter by forming a body of a wavelength converting material having a width, a length, and a height, wherein a cross-section of the body in the length direction has a shape such that, when the wavelength converter is installed over the LED die, the height of the body is larger adjacent the region of the LED die that produces the peak luminance; and
mechanically coupling the shaped luminance LED die and the wavelength converter together.

16. The method of claim 15, wherein the producing the wavelength converter further comprises:
selecting properties for the wavelength converter,
generating a simulated v′ cross section graph based on the selected properties for the wavelength converter and properties of the shaped luminance LED die,
determining a degree of color shift from the generated simulated v′ cross section graph, and
selecting values for an angle of incline of at least one surface or edge of the wavelength converter based on the determined degree of color shift that result in an optimized degree of color shift and the height of the body being larger adjacent the region of the LED die that produces the peak luminance by an optimized amount.

17. The method of claim 15, wherein the peak luminance is an area of alight-emitting area (LEA) of the LED die wherein the luminance of light emitted from the area of the LEA deviates most from an average of the luminance of the LED averaged over the entirety of the LEA.

18. The method of claim 16, wherein the producing the wavelength converter further comprises:
obtaining a brown body,
selecting at least one dicing blade for dicing the brown body based on the selected values for the angle of inclination and a chosen shape of the wavelength converter, and
dicing the brown body into the chosen shape using the selected at least one blade and making at least one pass with the selected at least one blade.

19. The method of claim 16, wherein the shape of the wavelength converter is chosen from the group consisting of an asymmetric truncated pyramid shape, or a ramp shape.

20. The method of claim 16, wherein the producing the wavelength converter further comprises:
forming a laminated green body from a plurality of green body pieces,
performing pressing on the laminated green body using a mold to shape uppermost ones of the green body pieces into a wafer of wavelength converters, each having the chosen shape, and
dicing the wafer to form a plurality of separated wavelength converters, each having the chosen shape.
